(19) United States
(12) Patent Application Publication
(10) Pub. No.: US 2005/0140414 A1
(43) Pub. Date: Jun. 30, 2005

(54) Delay circuit and display including the same

(75) Inventor: Michiru Senda, Gifu-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/016,800

(22) Filed: Dec. 21, 2004

(30) Foreign Application Priority Data
Dec. 24, 2003 (JP) JP2003-426879

(51) Int. Cl. H03K 5/153

(52) U.S. Cl. 327/261

(57) ABSTRACT

A delay circuit capable of suppressing reduction of the yield in manufacturing is provided. This delay circuit comprises an inverter circuit having a prescribed logical threshold voltage and a first transistor connected in parallel to the inverter circuit. The first transistor is turned on when an input signal in and an output signal from the inverter circuit are at a first voltage and a second voltage respectively and further turned on for at least a partial period in a period when the input signal in the inverter circuit reaches a voltage corresponding to the logical threshold voltage of the inverter circuit from the first voltage for changing from the first voltage to the second voltage thereby functioning substantially as a capacitor.

### BACKGROUND OF THE INVENTION

### FIELD OF THE INVENTION

The present invention relates to a delay circuit and a display including the same, and more particularly, it relates to a delay circuit employing an inverter circuit and a display including the same.

### CROSS-REFERENCE TO RELATED APPLICATIONS The priority application number JP2003-426879 upon which this patent application is based is hereby incorporated by reference.

### DESCRIPTION OF THE BACKGROUND ART

In general, a delay circuit employing an inverter circuit is known as disclosed in Japanese Patent Laying-Open No. 5-14152 (1993), for example. The aforementioned Japanese Patent Laying-Open No. 5-14152 discloses a delay circuit formed by serially connecting a plurality of inverter circuits with each other.

FIG. 12 is a circuit diagram for illustrating the structure of a display including delay circuits similar to that disclosed in the aforementioned Japanese Patent Laying-Open No. 5-14152. FIGS. 13 and 14 are circuit diagrams showing the structures of the delay circuits included in the conventional display shown in FIG. 12. Referring to FIG. 12, the conventional display including delay circuits is provided with shift register circuits 101 to 103, inverter circuits 104 to 106, buffers 107 to 109, p-type switching transistors PT101 to PT103 and n-type switching transistors NT101 to NT103.

The first- to third-stage shift registers 101 to 103 have functions of signals shifted in timing respectively. The first-stage shift register circuit 101 is supplied with a start signal START. The second-stage shift register 102 is connected to the output side of the first-stage shift register circuit 102, while the third-stage shift register circuit 103 is connected to the output side of the second-stage shift register circuit 102. Thus, the first- to third-stage shift register circuits 101 to 103 are supplied with the start signal START or output signals SR101 and SR102 from the preceding shift register circuits 101 and 102 respectively, thereby sequentially outputting the signals shifted in timing.

The output signal SR101 from the first-stage shift register circuit 101 is also supplied to the buffer 107. The buffer 107 is constituted of a delay circuit 107a for delaying a low-level signal (ON signal) supplied to the gate of the p-type switching transistor PT101 and a delay circuit 107b for delaying a high-level signal (ON signal) supplied to the gate of the n-type switching transistor NT101. The output signal SR101 supplied to the buffer 107 is divided into two signals. The first one of the divided signals is directly supplied to the delay circuit 107a of the buffer 107, while the second signal is supplied to the delay circuit 107b of the buffer 107 through the inverter circuit 104.

In the delay circuit 107a for the switching transistor PT101, three inverter circuits 110, 111 and 112 are serially connected with each other as shown in FIG. 13. These three inverter circuits 110, 111 and 112 are so formed that the ratios Wn/Wp between the gate widths Wn and Wp of n-channel transistors (not shown) and p-channel transistors (not shown) constituting the three inverter circuits 110, 111 and 112 respectively are 30 μm/100 μm, 30 μm/50 μm and 300 μm/150 μm respectively. Thus, the delay circuit 107a is so constituted that the time delay of a low-level output signal at the time when an input signal goes up from a low level to a high level is larger than the time delay of a high-level output signal at the time when the input signal goes down from a high level to a low level. In the delay circuit 107b for the switching transistor NT101, on the other hand, three inverter circuits 113, 114 and 115 are serially connected with each other. These three inverter circuits 113, 114 and 115 are so formed that the ratios Wn/Wp between the gate widths Wn and Wp of n-channel transistors (not shown) and p-channel transistors (not shown) constituting the three inverter circuits 113, 114 and 115 are respectively 10 μm/30 μm, 100 μm/10 μm and 100 μm/200 μm respectively. Thus, the delay circuit 107b is so constituted that the time delay of a high-level output signal at the time when an input signal goes down from a high level to a low level is larger than the time delay of a low-level output signal at the time when the input signal goes up from a low level to a high level. Further, the time delay by the delay circuit 107b for the switching transistor NT101 is equal to the time delay by the delay circuit 107a for-the switching transistor PT101.

As shown in FIG. 12, the output of the delay circuit 107a is connected to the gate of the switching transistor PT101, while the output of the delay circuit 107b is connected to the gate of the switching transistor NT101. The source of the switching transistor PT101 and the drain of the switching transistor NT101 are connected to a video signal line Video respectively. The drain of the switching transistor PT101 and the source of the switching transistor NT101 are connected to a drain line connected to an image display portion (not shown).

An inverter circuit 105, a buffer 108, a p-type switching transistor PT102 and an n-type switching transistor NT102 connected to the second-stage shift register circuit 102 and an inverter circuit 106, a buffer 109, a p-type switching transistor PT103 and an n-type switching transistor NT103 connected to the third-stage shift register circuit 103 are constituted similarly to the inverter circuit 104, the buffer 107, the p-type switching transistor PT101 and the n-type switching transistor NT101 connected to the aforementioned first-stage shift register circuit 101 respectively. A delay circuit 108a for the switching transistor PT102 constituting the second-stage buffer 108 and a delay circuit 109a for the switching transistor PT103 constituting the third-stage buffer 109 are constituted similarly to the delay circuit 107a for the switching transistor PT101 of the aforementioned first-stage buffer 107 respectively. Further, a delay circuit 108b for the switching transistor NT102 and a delay circuit 109b for the switching transistor NT103 are constituted similarly to the delay circuit 107b for the switching transistor NT101 of the aforementioned first-stage buffer 107 respectively. Circuits connected to fourth and subsequent stages of shift register circuits are constituted similarly to the circuits connected to the aforementioned first- to third-stage shift registers 101 to 103 respectively.

FIG. 15 is a voltage waveform diagram for illustrating operations of the conventional display including delay circuits. Referring to FIG. 15, all output signals SR101 to SR103 from the first- to third-stage shift register circuits 101 to 103 are at low levels in an initial state in the conventional display including delay circuits. Thus, all signals VPT101 to VPT103 input from the first- to third-stage delay circuits 107a to 109a in the gates of the switching transistors PT101 to PT103 respectively are held at high levels. On the other hand, all signals VNT101 to VNT103 input from the first- to third-stage delay circuits 107b to 109b in the gates of the switching transistors NT101 to NT103 respectively are held at low levels. Thus, all of the first- to third-stage switching transistors PT101 to PT103 and NT101 to NT103 are kept in OFF states.

Then, the output signal SR101 from the first-stage shift register circuit 101 goes up from the low level to a high level. Thus, the signals VPT101 and VNT101 input in the gates of the switching transistors PT101 and NT101 respectively are delayed by a time delay T101 due to the actions of the delay circuits 107a and 107b and converted to low and high levels respectively. Therefore, the first-stage switching transistors PT101 and NT101 are turned on in a delay by the time delay T101 respectively. Thus, a video signal is supplied from the video signal line Video to the corresponding drain line through the switching transistors PT101 and NT101.

Then, the output signal SR102 from the second-stage shift register circuit 102 goes up from the low level to a high level. Thus, the signals VPT102 and VNT102 input in the gates of the switching transistors PT102 and NT102 are delayed by the time delay T101 due to the actions of the delay circuits 108a and 108b and converted to low and high levels respectively. Therefore, the second-stage switching transistors PT102 and NT102 are turned on in a delay by the time delay T101 respectively. Thus, the video signal is supplied from the video signal line Video to the corresponding drain line through the switching transistors PT102 and NT102.

Then, the output signal SR103 from the third-stage shift register circuit 103 goes up from the low level to a high level. Thus, the signals VPT103 and VNT103 input in the gates of the switching transistors PT103 and NT103 are delayed by the time delay T101 due to the actions of the delay circuits 109a and 109b and converted to low and high levels respectively. Therefore, the third-stage switching transistors PT103 and NT103 are turned on in a delay by the time delay T101 respectively. Thus, the video signal is supplied from the video signal line Video to the corresponding drain line through the switching transistors PT103 and NT103.

When the output signal SR103 from the third-stage shift register circuit 103 goes up from the low level to a high level, on the other hand, the output signal SR101 from the first-stage shift register circuit 101 simultaneously goes down from the high level to a low level. Thus, the signals VPT101 and VNT101 input in the gates of the switching transistors PT101 and NT101 are converted to high and low levels respectively in a delay by a time delay T102 due to the actions of the delay circuits 107a and 107b. Therefore, the first-stage switching transistors PT101 and NT101 are turned off in a delay by the time delay T102 respectively.

This time delay T102 is smaller than the time delay T101 at the time when the third-stage switching transistors PT103 and NT103 are turned on, whereby the timing for turning off the third-stage switching transistors PT103 and NT103 is inhibited from overlapping with the timing for turning off the first-stage switching transistors PT101 and NT101. Thus, no noise results from the third-stage switching transistors PT103 and NT103 entering ON states before the first-stage switching transistors PT101 and NT101 enter OFF states.

Also in the fourth and subsequent stages of circuits, switching transistors are sequentially turned on without overlapping with the timing for turning off the preceding circuits but one respectively. Thus, the video signal is sequentially supplied from the video signal line Video to the corresponding drain lines through the switching transistors with no noise.

However, the conventional delay circuits 107a to 109a and 107b to 109b shown in FIGS. 13 and 14 delay the output signals for turning on the switching transistors PT101 to PT103 and NT101 to NT103 from those for turning off the same by increasing the ratios between the gate widths of the p-channel transistors and the n-channel transistors constituting the inverter circuits 110 to 115, and hence the gates of the p- or n-channel transistors constituting the inverter circuits 110 to 115 must disadvantageously have extremely small gate widths. Consequently, the yield is disadvantageously reduced in formation of the delay circuits 107a to 109a and 107b to 109b.

### SUMMARY OF THE INVENTION

The present invention has been proposed in order to provide a delay circuit capable of suppressing reduction of the yield in manufacturing.

The present invention has also been proposed in order to provide a display including a delay circuit capable of suppressing reduction of the yield in manufacturing.

In order to solve the aforementioned problem, a delay circuit according to a first aspect of the present invention comprises an inverter circuit having a prescribed logical threshold voltage and a first transistor connected in parallel to the inverter circuit. The first transistor is turned on when an input signal in and an output signal from the inverter circuit are at a first voltage and a second voltage respectively and further turned on for at least a partial period in a period when the input signal in the inverter circuit reaches a voltage corresponding to the logical threshold voltage of the inverter circuit from the first voltage for changing from the first voltage to the second voltage thereby functioning substantially as a capacitor.

The delay circuit according to the first aspect can increase the time for bringing the input signal in the inverter circuit from the first voltage to the voltage corresponding to the logical threshold voltage of the inverter circuit due to the action of the first transistor functioning substantially as a capacitor. Thus, the delay circuit can increase the time delay of the output signal at the time when the input signal in the inverter circuit changes from the first voltage to the second voltage without extremely increasing the ratio between the gate widths of transistors constituting the inverter circuit dissimilarly to the conventional delay circuit. Therefore, the delay circuit can increase the time delay of the output signal at the time when the input signal in the inverter circuit changes from the first voltage to the second voltage without extremely reducing the gate widths of the transistors constituting the inverter circuit, whereby the yield can be inhibited from reduction in formation of the delay circuit.

A display including a delay circuit according to a second aspect of the present invention comprises a shift register circuit outputting a signal shifted in timing, a buffer including a delay circuit connected to the output side of the shift register circuit and a switching transistor having a gate connected to the output side of the buffer as well as a source and a drain, one of which is connected to a signal line for supplying a video signal so that the other one is connected to a drain line connected to an image display portion. The delay circuit includes an inverter circuit having a prescribed logical threshold voltage and a first transistor connected in parallel to the inverter circuit, and the first transistor is turned on when an input signal in and an output signal from the inverter circuit are at a first voltage and a second voltage respectively and further turned on for at least a partial period in a period when the input signal in the inverter circuit reaches a voltage corresponding to the logical threshold voltage of the inverter circuit from the first voltage for changing from the first voltage to the second voltage thereby functioning substantially as a capacitor.

The display including a delay circuit according to the second aspect can increase the time for bringing the input signal in the inverter circuit from the first voltage to the voltage corresponding to the logical threshold voltage of the inverter circuit due to the action of the first transistor functioning substantially as a capacitor. Thus, the display can increase the time delay of the output signal at the time when the input signal in the inverter circuit changes from the first voltage to the second voltage without extremely increasing the ratio between the gate widths of transistors constituting the inverter circuit dissimilarly to the conventional delay circuit. Therefore, the display can increase the time delay of the output signal at the time when the input signal in the inverter circuit changes from the first voltage to the second voltage without extremely reducing the gate widths of the transistors constituting the inverter circuit, whereby the yield can be inhibited from reduction in formation of the delay circuit. Consequently, the yield can be inhibited from reduction in formation of the display including the delay circuit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing the overall structure of a display including delay circuits according to an embodiment of the present invention;

FIG. 2 is a circuit diagram showing the structure of a portion of a horizontal switch and an H driver of the display according to the embodiment of the present invention shown in FIG. 1;

FIGS. 3 and 4 are circuit diagrams showing the structures of the delay circuits included in the display according to the embodiment of the present invention shown in FIG. 1;

FIG. 5 is a circuit diagram showing the structure of a portion A of the delay circuit according to the embodiment of the present invention shown in FIG. 3;

FIG. 6 is a circuit diagram showing the structure of a portion B of the delay circuit according to the embodiment of the present invention shown in FIG. 4;

FIG. 7 is a voltage waveform diagram for illustrating operations of the display including delay circuits according to the embodiment of the present invention;

FIGS. 8 and 9 are voltage waveform diagrams for illustrating operations of the delay circuits according to the embodiment of the present invention;

FIG. 10 is a voltage waveform diagram showing results of a simulation performed with the delay circuit according to the embodiment of the present invention shown in FIG. 3;

FIG. 11 is a voltage waveform diagram showing results of a simulation performed with the delay circuit according to the embodiment of the present invention shown in FIG. 4;

FIG. 12 is a circuit diagram for illustrating the structure of a conventional display including delay circuits;

FIGS. 13 and 14 are circuit diagrams showing the structures of the delay circuits included in the conventional display; and

FIG. 15 is a voltage waveform diagram for illustrating operations of the conventional display including delay circuits.

### DESCRIPTION OF THE PREFERRED EMBODIMENTS

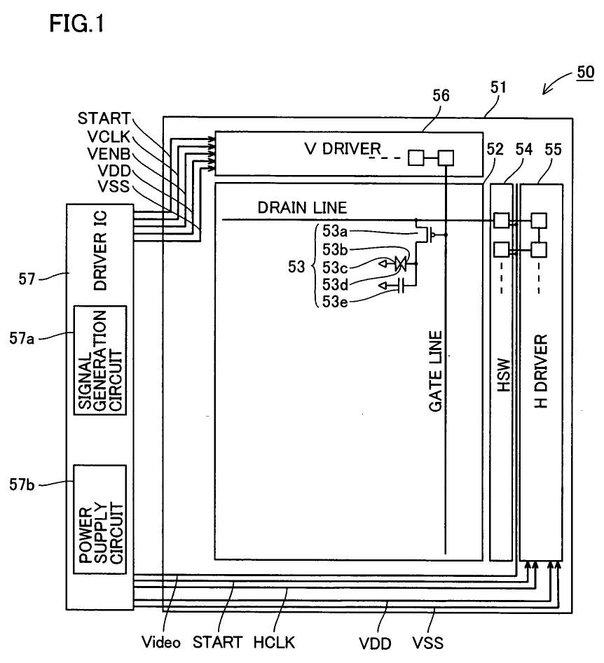

An embodiment of the present invention is now described with reference to FIGS. 1 to 11.

First, the structures of delay circuits and a display 50 including the same according to this embodiment are described with reference to FIGS. 1 to 6.

In the display 50 including delay circuits according to this embodiment, an image display portion 52 is provided on a substrate 51, as shown in FIG. 1. Pixels 53 are arranged on the image display portion 52 in the form of a matrix. FIG. 1 shows the structure of only one pixel 53 of the image display portion 52. Each pixel 53 is constituted of a p-channel transistor 53a, a pixel electrode 53b, a common electrode 53c, common to the respective pixels 53, arranged oppositely to the pixel electrode 53b, a liquid crystal 53b held between the pixel electrode 53b and the common electrode 53c and a subsidiary capacitance 53e. The p-channel transistor 53a has a source connected to a drain line, a drain connected to the pixel electrode 53b and the subsidiary capacitance 53e and a gate connected to a gate line.

A horizontal switch (HSW) 54 and an H driver 55 for driving (scanning) the drain lines of the image display portion 52 are provided on the substrate 51 along an edge of the image display portion 52. A V driver 56 for driving (scanning) the gate lines of the image display portion 52 is provided on the substrate 51 along another edge of the image display portion 52. A driver IC 57 is set outside the substrate 51. This driver IC 57 comprises a signal generation circuit 57a and a power supply circuit 57b. A video signal line Video for supplying a video signal is connected from the driver IC 57 to the horizontal switch 54. The driver IC 57 supplies the H driver 55 with a start signal START, a clock signal HCLK, a high power supply voltage VDD and a low power supply voltage VSS. The driver IC 57 further supplies the V driver 56 with the start signal START, a clock signal VCLK, an enable signal VENB, the high power supply source VDD and the low power supply source VSS.

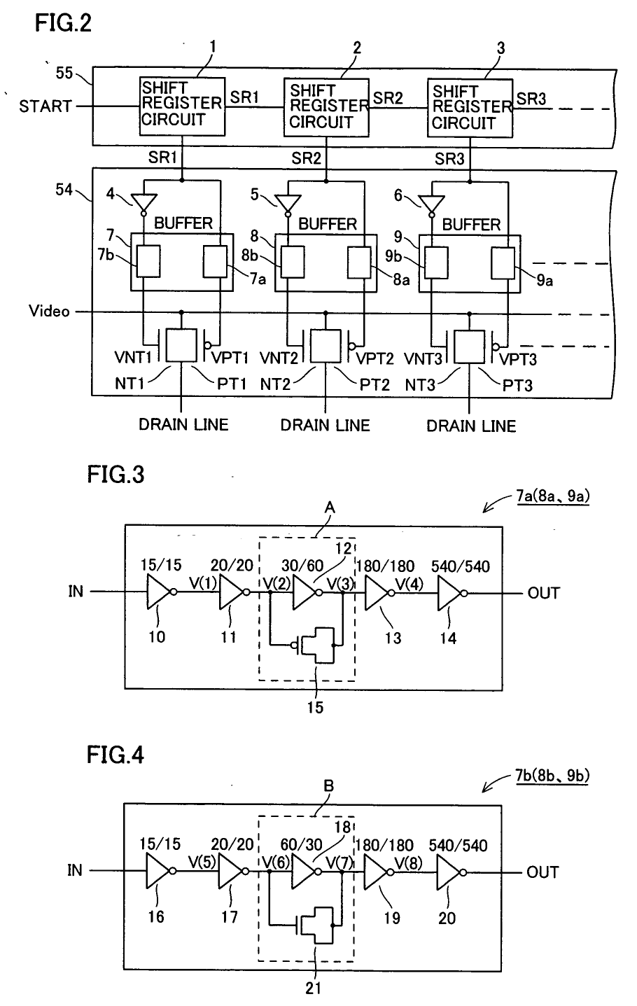

As shown in FIG. 2, the H driver 55 includes shift register circuits 1 to 3, and the horizontal switch 54 includes inverter circuits 4 to 6, buffers 7 to 9, p-type switching transistors PT1 to PT3 and n-type switching transistors NT1 to NT3. The p-type switching transistors PT1 to PT3 are examples of the “switching transistor” or the “first switching transistor” in the present invention, and the n-type switching transistors NT1 to NT3 are examples of the “switching transistor” or the “second switching transistor” in the present invention. FIG. 2 shows only the structures of circuits connected to the three stages of shift register circuits 1 to 3, in order to simplify the illustration.

The first- to third-stage shift registers 1 to 3 of the H driver 55 have functions of outputting signals shifted in timing respectively. The first-stage shift register circuit 1 is supplied with the start signal START. The second-stage shift register circuit 2 is connected to the output side of the first-stage shift register circuit 1, while the third-stage shift register circuit 3 is connected to the output side of the second-stage shift register circuit 3. Thus, the first- to third-stage shift registers 1 to 3 are supplied with the start signal START and output signals SR1 and SR2 from the preceding shift registers 1 and 2 respectively, thereby sequentially outputting the signals-shifted in timing respectively.

The output signal SR1 from the first-stage shift register circuit 1 is also supplied to the buffer 7 of the horizontal switch 54. The buffer 7 is constituted of a delay circuit 7a for delaying a low-level signal (ON signal) to the gate of the p-type switching transistor PT1 and a delay circuit 7b for delaying a high-level signal (ON signal) to the gate of the n-type switching transistor NT1. The delay circuit 7a is an example of the “first delay circuit” in the present invention, and the delay circuit 7b is an example of the “second delay circuit” in the present invention. The output signal SR1 supplied to the buffer 7 is divided into two signals. One of the divided signals is directly supplied to the delay circuit 7a of the buffer 7, while the second signal is supplied to the delay circuit 7b of the buffer 7 through the inverter circuit 4.

As shown in FIG. 3, the delay circuit 7a for the switching transistor PT1 is constituted of five inverter circuits 10 to 14 and a p-channel transistor 15. The inverter circuit 12 is an example of the “first inverter circuit” in the present invention, and the p-channel transistor 15 is an example of the “first transistor” in the present invention. The five inverter circuits 10 to 14 are serially connected with each other. The signal directly supplied from the shift register circuit 1 to the buffer 7 is input in the inverter circuit 10 of the delay circuit 7a, while the inverter circuit 14 outputs an output signal from the delay circuit 7a.

According to this embodiment, the gate of the p-channel transistor 15 is connected to the input side of the inverter circuit 12 while both of the source and the drain thereof are connected to the output side of the inverter circuit 12, as shown in FIG. 3. Thus, the p-channel transistor 15 is turned on when the input signal in and the output signal from the inverter circuit 12 are at low and high levels respectively, and turned off when the input signal in and the output signal from the inverter circuit 12 are at high and low levels respectively. The low level is an example of the “low voltage” in the present invention, and the high level is an example of the “high voltage” in the present invention. The p-channel transistor 15 has a threshold voltage Vth corresponding to the voltage difference between the output side and the input side of the inverter circuit 12 at the time when the input signal in the inverter circuit 12 reaches a voltage corresponding to the logical threshold voltage of the inverter circuit 12 from the low level. The p-channel transistor 15 is constituted to function as a capacitor in an ON state and not to function substantially as a capacitor in an OFF state.

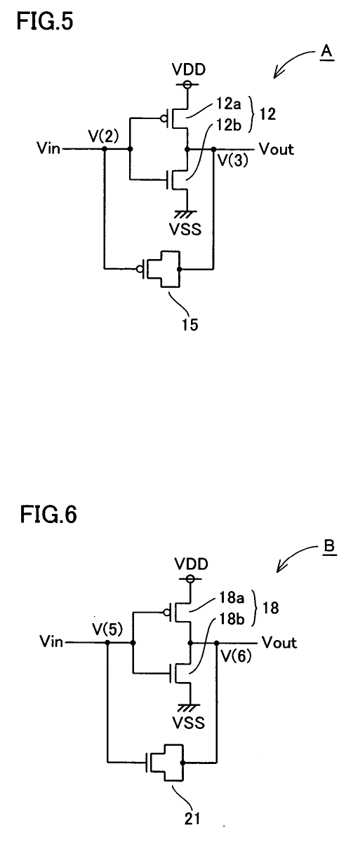

As shown in FIG. 5, the inverter circuit 12 has a CMOS structure formed by a p-channel transistor 12a and an n-channel transistor 12b. The p-channel transistor 12a is an example of the “second transistor” in the present invention, and the n-channel transistor 12b is an example of the “third transistor” in the present invention. The source of the p-channel transistor 12a is connected to the high voltage supply source VDD, while the source of the n-channel transistor 12b is connected to the low voltage supply source VSS. In the inverter circuit 12, the n-channel transistor 12b has a gate width smaller than that of the p-channel transistor 12a, and the ratio Wn/Wp between the gate widths of the n-channel transistor 12b and the p-channel transistor 12a is set to 30 μm/60 μm. The n-channel transistor 12b has a gate length not less than that of the p-channel transistor 12a. Thus, the logical threshold voltage of the inverter circuit 12 is stepped up.

The inverter circuits 10, 11, 13 and 14 (see FIG. 3) have CMOS structures similar to that of the aforementioned inverter circuit 12. However, the inverter circuits 10, 11, 13 and 14 are so constituted that the gate widths of n-channel transistors and p-channel transistors are equal to each other. More specifically, the ratios Wn/Wp between the gate widths of the n-channel transistors and the p-channel transistors are set to 15 μm/15 μm, 20 μm/20 μm, 180 μm/180 μm and 540 μm/540 μm in the inverter circuits 10, 11, 13 and 14 respectively.

As shown in FIG. 4, inverter circuits 16, 17, 19 and 20 of the delay circuit 7b of the buffer 7 are constituted similarly to the inverter circuits 10, 11, 13 and 14 of the aforementioned delay circuit 7a. In the delay circuit 7b, on the other hand, an n-channel transistor 21 is connected to an inverter circuit 18. The n-channel transistor 21 is an example of the “first transistor” in the present invention. The inverter circuit 18 connected with the n-channel transistor 21 has a CMOS structure formed by a p-channel transistor 18a and an n-channel transistor 18b, as shown in FIG. 6. The p-channel transistor 18a is an example of the “second transistor” in the present invention, and the n-channel transistor 18b is an example of the “third transistor” in the present invention. The n-channel transistor 18b has a gate width larger than that of the n-channel transistor 18a, and the ratio Wn/Wp between the gate widths of the n-channel transistor 18b and the p-channel transistor 18a is set to 60 μm/30 μm. The n-channel transistor 18b has a gate length not more than that of the p-channel transistor 18a. Thus, the logical threshold voltage of the inverter circuit 18 is stepped down.

The gate of the n-channel transistor 21 is connected to the input side of the inverter circuit 18, while both of the source and the drain thereof are connected to the output side of the inverter circuit 18. Thus, the n-channel transistor 21 is turned on when an input signal in and an output signal from the inverter circuit 18 are at high and low levels respectively, and turned off when the input signal in and the output signal from the inverter circuit 18 are at low and high levels respectively. The n-channel transistor 21 has a threshold voltage Vth corresponding to the voltage difference between the output side and the input side of the inverter circuit 18 at the when the input signal in the inverter circuit 18 reaches a voltage corresponding to the logical threshold voltage of the inverter circuit 18 from the high level.

The p-channel transistor 12a and the n-channel transistor 12b constituting the inverter circuit 12 (see FIG. 5), the p-channel transistor 15 connected to the inverter circuit 12, the p-channel transistor 18a and the n-channel transistor 18b constituting the inverter circuit 18 (see FIG. 6) and the n-channel transistor 21 connected to the inverter circuit 18 are formed by polysilicon TFTs (thin film transistors) formed on a single glass substrate respectively. This glass substrate is an example of the “insulated substrate” in the present invention, and the polysilicon TFTs are examples of the “polycrystalline thin-film transistor” in the present invention.

As shown in FIG. 2, the output of the delay circuit 7a is connected to the gate of the switching transistor PT1, while the output of the delay circuit 7b is connected to the gate of the switching transistor NT1. The source of the switching transistor PT1 and the drain of the switching transistor NT1 are connected to the video signal line Video respectively. The drain of the switching transistor PT1 and the source of the switching transistor NT1 are connected to a drain line connected to the corresponding pixel 53 (see FIG. 1) of the image display portion 52.

The inverter circuit 5, the buffer 8, the p-type switching transistor PT2 and the n-type switching transistor NT2 connected to the second-stage shift register circuit 2 and the inverter circuit 6, the buffer 9, the p-type switching transistor PT3 and the n-type switching transistor NT3 connected to the third-stage shift register circuit 3 are constituted similarly to the inverter circuit 4, the buffer 7, the p-type switching transistor PT1 and the n-type switching transistor NT1 connected to the aforementioned first-stage shift register circuit 1 respectively. Further, delay circuits 8a and 9a for the switching transistors PT2 and PT3 constituting the second- and third-stage buffers 8 and 9 are constituted similarly to the delay circuit 7a for the switching transistor PT1 of the aforementioned first-stage buffer 7 respectively. In addition, delay circuits 8b and 9b for the switching transistors NT2 and NT3 are constituted similarly to the delay circuit 7b for the switching transistor NT1 of the aforementioned first-stage buffer 7 respectively. Circuits connected to fourth and subsequent stages of shift register circuits are constituted similarly to the circuits connected to the aforementioned first- to third-stage shift register circuits 1 to 3 respectively.

Operations of the delay circuits and the display including the same according to this embodiment are now described with reference to FIGS. 1 to 9.

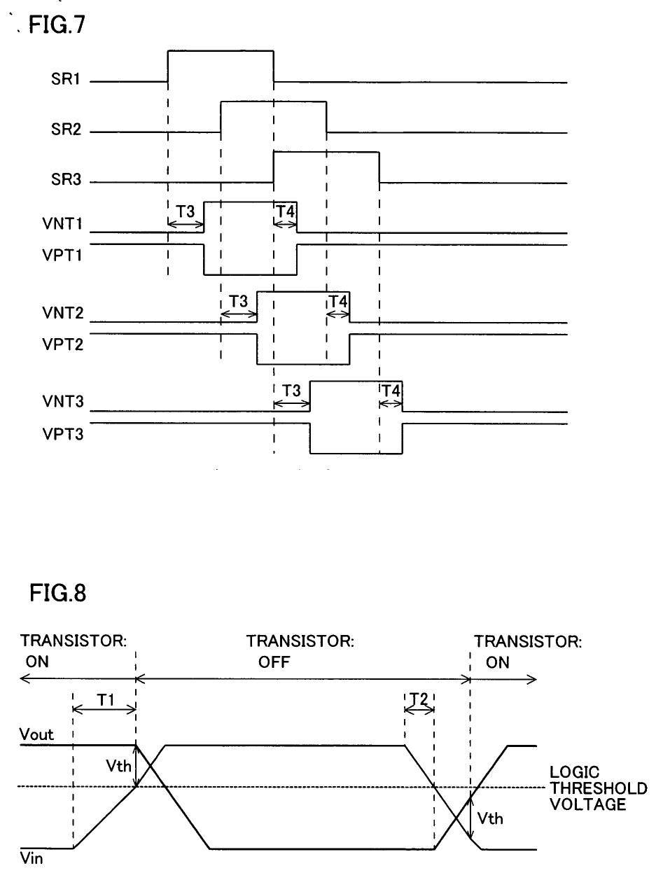

In an initial state, all output signals SR1 to SR3 from the first- to third-stage shift register circuits 1 to 3 are at low levels, as shown in FIG. 7. Thus, all signals VPT1 to VPT3 input from the delay circuits 7a to 9a of the first- to third-stage buffers 7 to 9 in the gates of the switching transistors PT1 to PT3 respectively are held at high levels. On the other hand, all signals VNT1 to VNT3 input from the delay circuits 7b to 9b of the first- to third-stage buffers 7 to 9 in the gates of the switching transistors NT1 to NT3 respectively are held at low levels. Thus, all of the first- to third-stage switching transistors PT1 to PT3 and NT1 to NT3 are kept in OFF states.

Then, the output signal SR1 from the first-stage shift register circuit 1 goes up from the low level to a high level. In the delay circuit 7a for the switching transistor PT1 of the buffer 7 shown in FIG. 3, therefore, an input signal Vin input in the inverter circuit 12 goes up from a low level to a high level, as shown in FIG. 8. At this time, the time for bringing the input signal Vin from the low level to a voltage corresponding to the logical threshold voltage is increased due to the stepped-up logical threshold voltage of the inverter circuit 12 in this embodiment. In the period for bringing the input signal Vin from the low level to the voltage corresponding to the logical threshold voltage of the inverter circuit 12, the p-channel transistor 15 is kept in an ON state. Thus, the p-channel transistor 15 functions as a capacitor in this period, thereby further increasing the time for bringing the input signal Vin from the low level to the voltage corresponding to the logical threshold voltage. Therefore, the timing for starting lowering an output signal Vout from the inverter circuit 12 from a high level to a low level is delayed by a time delay T1. Thus, the inverter circuit 12 outputs the low-level output signal Vout in a delay by the time delay T1. The p-channel transistor 15 connected to the inverter circuit 12 has the threshold voltage Vth corresponding to the voltage difference between the output side and the input side of the inverter circuit 12 at the time when the input signal Vin reaches the voltage corresponding to the logical threshold voltage of the inverter circuit 12. Thus, the p-channel transistor 15 is turned off when the input signal Vin reaches the voltage corresponding to the logical threshold voltage of the inverter circuit 12, not to function substantially as a capacitor.

The low-level output signal Vout is input in the gate of the switching transistor PT1 from the inverter circuit 12 through the two-stage inverter circuits 13 and 14 (see FIG. 3). Thus, the signal VPT1 input in the gate of the switching transistor PT1 goes down from the high level to a low level, as shown in FIG. 7. The timing for lowering the signal VPT1 to a low level is delayed by a time delay T3 from the timing for raising the output signal SR1 to a high level. This time delay T3 corresponds to the sum of time delays by the inverter circuits 10, 11, 13 and 14 and the time delay T1 by the inverter circuit 12 and the p-channel transistor 15. The signal VPT1 goes down to a low level for turning on the switching transistor PT1.

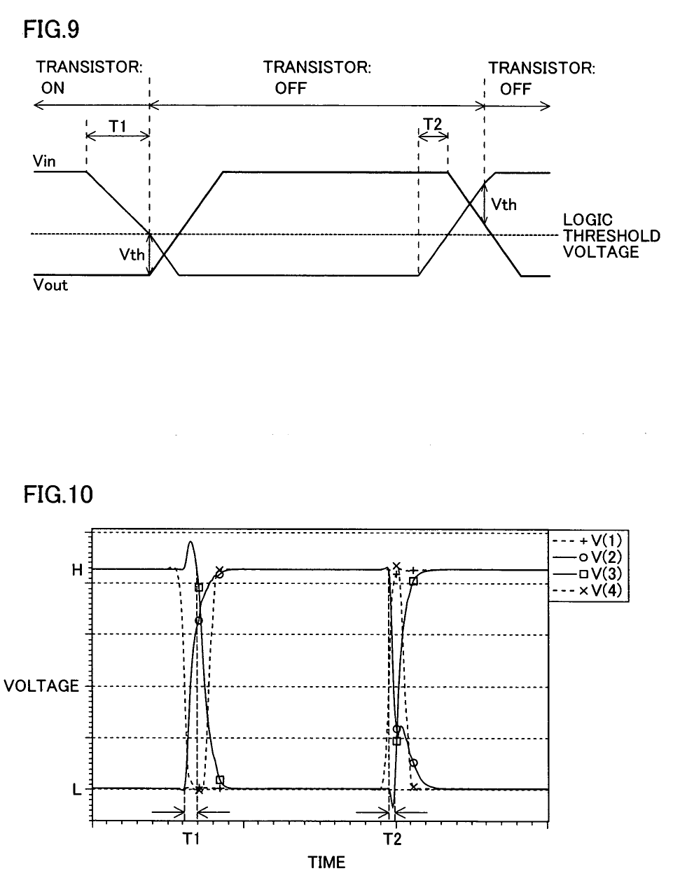

In the delay circuit 7b for the switching transistor NT1 of the buffer 7 shown in FIG. 4, on the other hand, an input signal Vin input in the inverter circuit 18 through the inverter circuits 4, 16 and 17 goes down from a high level to a low level when the output signal SR1 from the first-stage shift register circuit 1 goes up from the low level to a high level. At this time, the time for bringing the input signal Vin from the high level to a voltage corresponding to the logical threshold voltage is increased due to the stepped-down logical threshold voltage of the inverter circuit 18 in this embodiment, as shown in FIG. 9. The n-channel transistor 21 is kept in an ON state in the period for bringing the input signal Vin from the high level to the voltage corresponding to the logical threshold voltage of the inverter circuit 18. Thus, the n-channel transistor 21 functions as a capacitor in this period, thereby further increasing the time for bringing the input signal Vin from the high level to the voltage corresponding to the logical threshold voltage. Therefore, the timing for starting raising an output signal Vout from the inverter circuit 18 from a low level to a high level is delayed by the time delay T1. Thus, the inverter circuit 18 outputs the high-level output signal Vout in a delay by the time delay T1. The n-channel transistor 21 has the threshold voltage Vth corresponding to the voltage difference between the output side and the input side of the inverter circuit 18 at the time when the input signal Vin reaches the voltage corresponding to the logical threshold voltage of the inverter circuit 18. Thus, the n-channel transistor 21 is turned off when the input signal Vin reaches the voltage corresponding to the logical threshold voltage of the inverter circuit 18, not to function substantially as a capacitor.

The high-level output signal Vout is input in the gate of the switching transistor NT1 from the inverter circuit 18 through the two-stage inverter circuits 19 and 20 (see FIG. 4). Thus, the signal VNT1 input in the gate of the switching transistor NT1 goes up from the low level to a high level, as shown in FIG. 7. The timing for raising the signal VNT1 to a high level is delayed by the time delay T3 from the timing for raising the output signal SR1 to a high level. This time delay T3 corresponds to the sum of time delays by the inverter circuits 16, 17, 19 and 20 and the time delay Ti by the inverter circuit 18 and the n-channel transistor 21. The signal VNT1 goes up to a high level for turning on the switching transistor NT1. As hereinabove described, both of the switching transistors PT1 and NT1 are turned on so that the video signal line Video supplies the video signal to the corresponding drain line through the switching transistors PT1 and NT1. The video signal supplied to the drain line is supplied to the corresponding pixel 53 (see FIG. 1) of the image display portion 52 from the drain line.

Then, the output signal SR1 from the first-stage shift register circuit 1 is input in the second-stage shift register circuit 2, which in turn outputs a high-level output signal SR2 shifted in timing. Thus, the signal VPT2 input in the gate of the switching transistor PT2 goes down from the high level to a low level while the signal VNT2 input in the gate of the switching transistor NT2 goes up from the low level to a high level through operations similar to those of the circuits connected to the aforementioned first-stage shift register circuit 1. At this time, the timing for lowering and raising the signals VPT2 and VNT to low and high levels respectively is delayed by the time delay T3 from the timing for raising the output signal SR2 from the second-stage shift register circuit 2 from the low level to a high level. The signals VPT2 and VNT2 change to low and high levels respectively, thereby turning on both of the switching transistors PT2 and NT2. Thus, the video signal Video supplies the video signal to the corresponding drain line through the switching transistors PT2 and NT2. The video signal supplied to the drain line is supplied to the corresponding pixel 53 (see FIG. 1) of the image display portion 52 from the drain line.

Then, the output signal SR2 from the second-stage shift register circuit 2 is input in the third-stage shift register circuit 3, which in turn outputs a high-level output signal SR3 shifted in timing with respect to the output signal SR2. The signals VPT3 and VNT3 input in the gates of the switching transistors PT3 and NT3 change to low and high levels respectively in a delay by the time delay T3 due to operations similar to those of the circuits connected to the aforementioned second-stage shift register circuit 2. The signals VPT3 and VNT3 change to the low and high levels respectively, thereby turning on both of the switching transistors PT3 and NT3. Thus, the video signal line Video supplies the video signal to the corresponding drain line through the switching transistors PT3 and NT3. The video signal supplied to the drain line is supplied to the corresponding pixel 53 (see FIG. 1) of the image display portion 52 from the drain line.

At the time when the output signal SR3 from the third-stage shift register circuit 3 goes up from the low level to a high level, on the other hand, the output signal SR1 from the first-stage shift register circuit 1 simultaneously goes down from the high level to a low level. In the delay circuit 7a of the first-stage buffer 7, therefore, the input signal Vin in the inverter circuit 12 goes down from the high level to a low level, as shown in FIG. 8. At this time, the time for bringing the input signal Vin from the high level to the voltage corresponding to the logical threshold voltage of the inverter circuit 12 is reduced due to the stepped-up logical threshold voltage of the inverter circuit 12 in this embodiment.

The p-channel transistor 15 is kept in an OFF state in the period for bringing the input signal Vin from the high level to the voltage corresponding to the logical threshold voltage of the inverter circuit 12, not to function as a capacitor. Thus, the time for bringing the input signal Vin from the high level to the voltage corresponding to the logical threshold voltage of the inverter circuit 12 is not increased. Therefore, the timing for starting raising the output signal Vout from the inverter circuit 12 from the low level to a high level is delayed by a time delay T2 smaller than the time delay T1. The timing for raising the signal VPT1 input in the gate of the switching transistor PT1 from the low level to a high level is delayed by a time delay T4 from the timing for lowering the output signal SR1 to a low level. This time delay T4 corresponds to the sum of time delays by the inverter circuits 10, 11, 13 and 14 of the delay circuit 7a and the time delay T2 by the inverter circuit 12 and the p-channel transistor 15. Therefore, this time delay T4 is smaller than the time delay T3 for the signal VPT at the time when the output signal SR1 from the shift register circuit 1 goes up from the low level to a high level. The signal VPT1 so goes up from the low level to a high level as to turn off the switching transistor PT1.

In the delay circuit 7b of the firs-stage buffer 7, on the other hand, an input signal Vin in the inverter circuit 18 goes up from a low level to a high level, as shown in FIG. 9. At this time, the time for bringing the input signal Vin from the low level to a voltage corresponding to the logical threshold voltage of the inverter circuit 18 is reduced due to the stepped-down logical threshold voltage of the inverter circuit 18 in this embodiment. The n-channel transistor 21 is kept in an OFF state in the period for bringing the input signal Vin from the low level to the voltage corresponding to the logical threshold voltage of the inverter circuit 18, not to function substantially as a capacitor. Thus, the time for bringing the input signal Vin from the low level to the voltage corresponding to the logical threshold voltage of the inverter circuit 18 is not increased. Therefore, the timing for starting lowering the output signal Vout from the inverter circuit 18 from a high level to a low level is delayed by the time delay T2 smaller than the time delay T1. The timing for lowering the signal VNT1 input in the gate of the switching transistor NT1 from the high level to a low level is delayed by the time delay T4 from the timing for lowering the output signal SR1 to a low level. This time delay T4 corresponds to the sum of time delays by the inverter circuits 16, 17, 19 and 20 of the delay circuit 7b and the time delay T2 by the inverter circuit 18 and the n-channel transistor 21. Therefore, this time delay T4 is smaller than the time delay T3 for the signal VNT1 at the time when the output signal SR1 from the shift register circuit 1 goes up from the low level to a high level. The signal VNT1 so goes down from the high level to a low level as to turn off the switching transistor NT1.

As hereinabove described, the time delay T4 for turning off both of the first-stage switching transistors PT1 and NT1 is smaller than the time delay T3. Thus, the timing for turning off both of the first-stage switching transistors PT1 and NT1 is inhibited from overlapping with the timing for turning on both of the third-stage switching transistors PT3 and NT3. Therefore, noise resulting from the third-stage switching transistors PT3 and NT3 entering ON states before the first-stage switching transistors PT1 and NT1 enter OFF states is suppressed.

Also in the fourth and subsequent stages of circuits, switching transistors are sequentially turned on without overlapping with the timing for turning off the preceding circuits but one respectively. Thus, the video signal is sequentially supplied from the video signal line Video to the corresponding drain lines through the switching transistors with no noise.

Results of simulations of time delays by the delay circuits 7a and 7b are now described with reference to FIGS. 3, 4, 10 and 11.

It is understood from FIG. 10 that the time delay T1 of an output signal V(3) (see FIG. 3) at the time when the voltage of an input signal V(2) (see FIG. 3) in the inverter circuit 12 goes up from a low level to a high level is larger than the time delay T2 of the output signal V(3) at the time when the voltage of the input signal V(2) in the inverter circuit 12 goes down from a high level to a low level in the delay circuit 7a. Thus, it has been proved possible to increase the time delay for a low-level output signal at the time when an input signal in the inverter circuit 12 goes up from a low level to a high level beyond the time delay of a high-level output signal at the time when the input signal goes down from a high level to a low level in the delay circuit 7a. It is also understood from FIG. 10 that the time delay of an output signal V(4) (see FIG. 3) from the inverter circuit 13 subsequent to the inverter circuit 12 with respect to an input signal V(1) (see FIG. 3) in the inverter circuit 11 preceding the inverter circuit 12 is larger than the time delay of the output signal V(3) with respect to the input signal V(2) in the inverter circuit 12. It is further understood that the time delay of the high-level output signal V(4) from the inverter circuit 13 at the time when the input signal V(1) in the inverter circuit 11 goes down from a high level to a low level is larger than the time delay of the low-level output signal V(4) at the time when the input signal V(1) goes up from a low level to a high level.

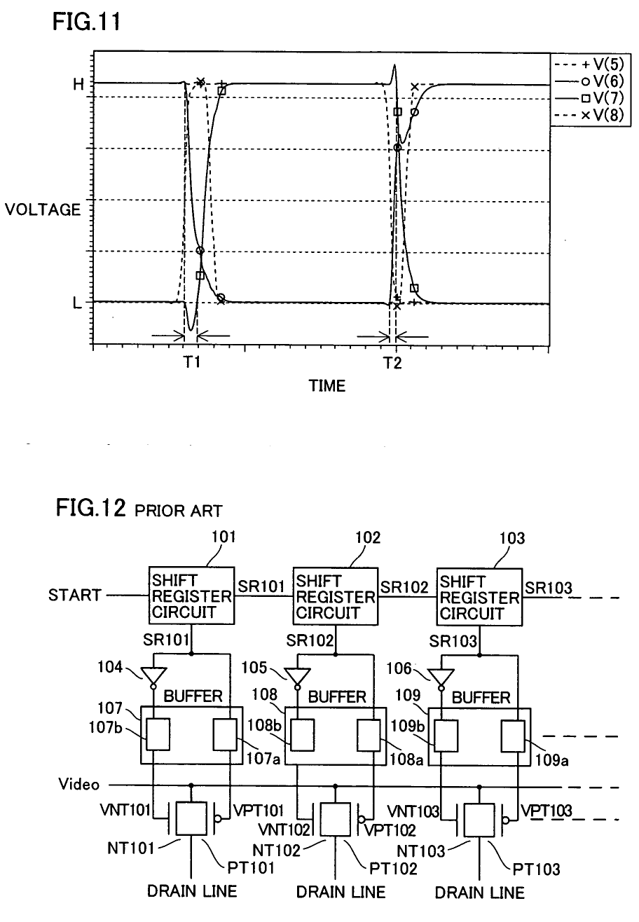

On the other hand, it is understood from FIG. 11 that the time delay T1 of an output signal V(7) (see FIG. 4) at the time when the voltage of an input signal V(6) (see FIG. 4) in the inverter circuit 18 goes down from a high level to a low level is larger than the time delay T2 of the output signal V(7) at the time when the voltage of the input signal V(6) in the inverter circuit 18 goes up from a low level to a high level in the delay circuit 7b. Thus, it has been proved possible to increase the time delay of a high-level output signal at the time when an input signal in the inverter circuit 18 goes down from a high level to a low-level beyond the time delay of a low-level output signal at the time when the input signal goes up from a low level to a high level in the delay circuit 7b. It is also understood from FIG. 11 that the time delay of an output signal V(8) (see FIG. 4) from the inverter circuit 19 subsequent to the inverter circuit 18 with respect to an input signal V(5) (see FIG. 4) in the inverter circuit 17 preceding the inverter circuit 18 is larger than the time delay of the output signal V(7) with respect to the input signal V(6) in the inverter circuit 18. It is further understood that the time delay of a low-level output signal V(8) from the inverter circuit 19 at the time when the input signal V(5) in the inverter circuit 17 goes up from a low level to a high level is larger than the time delay of a high-level output signal V(8) at the time when the input signal V(5) goes down from a high level to a low level.

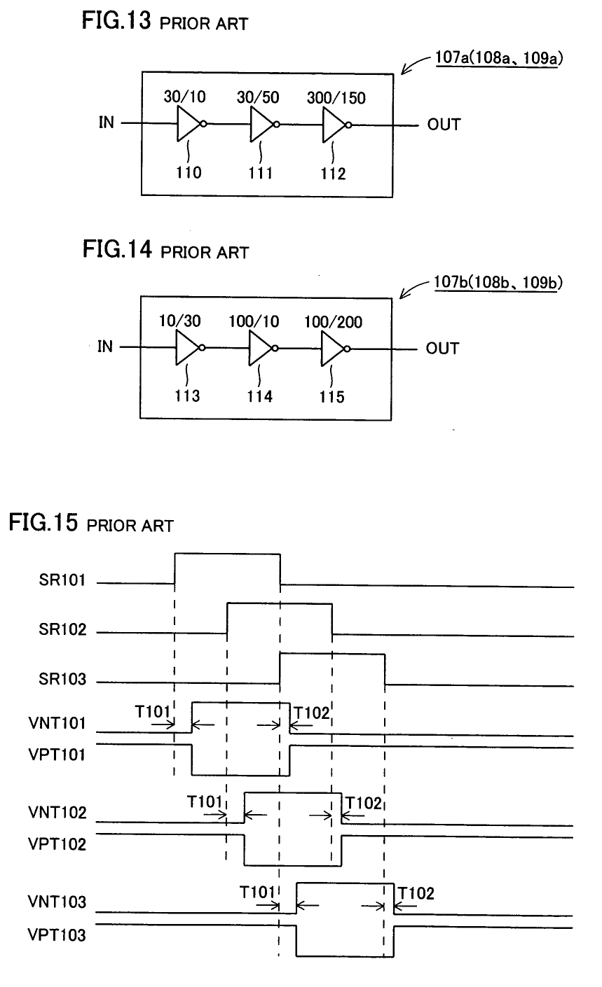

According to this embodiment, as hereinabove described, the p-channel transistor 15 turned on for the period for bringing the input signal in the inverter circuit 12, going up from a low level to a high level, from the low level to the voltage corresponding to the logical threshold voltage thereby functioning as a capacitor is so connected to the inverter circuit 12 that the time for bringing the input signal in the inverter circuit 12 from the low level to the voltage corresponding to the logical threshold voltage of the inverter circuit 12 can be increased due to the action of the p-channel transistor 15 functioning as a capacitor. Further, the n-channel transistor 21 turned on for the period for bringing the input signal in the inverter circuit 18, going down from a high level to a low level, from the high level to the voltage corresponding to the logical threshold voltage thereby functioning as a capacitor is so connected to the inverter circuit 18 that the time for bringing the input signal in the inverter circuit 18 from the high level to the voltage corresponding to the logical threshold voltage of the inverter circuit 18 can be increased due to the action of the n-channel transistor 21 functioning as a capacitor. As hereinabove described, the time delays for the output signals from the inverter circuits can be increased at the time when the input signals in the inverter circuits change from low levels to high levels or vice versa without remarkably increasing the ratios between the gate widths of the transistors constituting the inverter circuits, dissimilarly to the conventional delay circuits 107a and 107b (see FIGS. 13 and 14). Thus, the time delays for the output signals can be increased at the time when the input signals in the inverter circuits change from low levels to high levels or vice versa without remarkably reducing the gate widths of the transistors constituting the inverter circuits, whereby the yield can be inhibited from reduction in formation of the delay circuits. Consequently, the yield can be inhibited from reduction in formation of the display including the delay circuits.

According to this embodiment, the p-channel transistor 15 is turned off for the period for bringing the input signal in the inverter circuit 12, going down from a high level to a low level, from the low level to the voltage corresponding to the logical threshold voltage of the inverter circuit 12 not to function substantially as a capacitor, whereby the time delay for the output signal can be inhibited from increase when the input signal in the inverter circuit 12 goes down from the high level to a low level. Thus, the time delay T4 for the output signal from the delay circuit 7a at the time when the input signal in the inverter circuit 12 goes down from a high level to a low level can be reduced below the time delay T3 at the time when the input signal in the inverter circuit 12 goes up from a low level to a high level. Further, the n-channel transistor 21 is turned off for the period for bringing the input signal in the inverter circuit 18, going up from a low level to a high level, from the low level to the voltage corresponding to the logical threshold voltage of the inverter circuit 18 not to function substantially as a capacitor, whereby the time delay for the output signal can be inhibited from increase when the input signal in the inverter circuit 18 goes up from the low level to a high level. Thus, the time delay T4 for the output signal from the delay circuit 7a at the time when the input signal in the inverter circuit 12 goes down from a high level to a low level can be reduced below the time delay T3 at the time when the input signal in the inverter circuit 12 goes up from a low level to a high level, while the time delay T4 for the output signal from the delay circuit 7b at the time when the input signal in the inverter circuit 18 goes up from a low level to a high level can be reduced below the time delay T3 at the time when the input signal in the inverter circuit 18 goes down from a high level to a low level.

According to this embodiment, the p-channel transistor 12a, the n-channel transistor 12b and the p-channel transistor 15 are so formed by the polysilicon TFTs formed on the single glass substrate respectively that the time delay for the output signal from the inverter circuit 12 is increased due to the stepped-up logical threshold voltage of the inverter circuit 12 formed by the p-channel transistor 12a and the n-channel transistor 12b while the time delay for the output signal by the p-channel transistor 15 is reduced due to the stepped-up logical threshold voltage of the p-channel transistor 15 functioning as a capacitor when the threshold voltages of the p-channel transistor 12a, the n-channel transistor 12b and the p-channel transistor 15 are stepped up due to dispersion in the manufacturing process for the polysilicon TFTs. Thus, increase of the time delays for the output signals can be relaxed. When the threshold voltages of the p-channel transistor 12a, the n-channel transistor 12b and the p-channel transistor 15 are stepped down due to dispersion in the manufacturing process for the polysilicon TFTs, on the other hand, the time delay for the output signal from the inverter circuit 12 is reduced due to the stepped-down logical threshold voltage of the inverter circuit 12 formed by the p-channel transistor 12a and the n-channel transistor 12b while the time delay for the output signal by the p-channel transistor 15 is increased due to the stepped-down logical threshold voltage of the p-channel transistor 15 functioning as a capacitor. Thus, reduction of the time delays for the output signals is relaxed.

Although the present invention has been described and illustrated in detail, it is clearly understood that the same is by way of illustration and example only and is not to be taken by way of limitation, the spirit and scope of the present invention being limited only by the terms of the appended claims.

For example, the present invention is not restricted to the aforementioned embodiment but the inventive delay circuits are also applicable to another apparatus so far as the apparatus must render time delays for raising and lowering a prescribed signal waveform respectively different from each other.

The present invention is not restricted to the aforementioned embodiment but the inventive transistors functioning as capacitors may be connected to a plurality of inverter circuits included in the five inverter circuits. If the inventive transistors are connected to a plurality of adjacent inverter circuits respectively, the p- and n-channel transistors functioning as capacitors must alternately be connected.

The present invention is not restricted to the aforementioned embodiment but each shift register circuit may alternatively form an output signal and another output signal prepared by inverting the same and thereafter individually input these output signals in two delay circuits respectively.

The present invention is not restricted to the aforementioned embodiment but may alternatively be applied to a case of providing each buffer with a single delay circuit for a p- or n-type switching transistor.

The present invention is not restricted to the aforementioned embodiment but the gate width of an n-type third transistor may be substantially equalized with that of a p-type second transistor while the gate length of the n-type third transistor may be rendered larger than that of the p-type second transistor.

The present invention is not restricted to the aforementioned embodiment but the gate width of an n-type third transistor may be substantially equalized with that of a p-type second transistor while the gate length of the n-type third transistor may be rendered smaller than that of the p-type second transistor.

1. A delay circuit comprising:
an inverter circuit having a prescribed logical threshold voltage; and
a first transistor connected in parallel to said inverter circuit, wherein
said first transistor is turned on when an input signal in and an output signal from said inverter circuit are at a first voltage and a second voltage respectively and further turned on for at least a partial period in a period-when said input signal in said inverter circuit reaches a voltage corresponding to said logical threshold voltage of said inverter circuit from said first voltage for changing from said first voltage to said second voltage thereby functioning substantially as a capacitor.

2. The delay circuit according to claim 1, wherein
said first transistor is turned off when said input signal in and said output signal from said inverter circuit are at said second voltage and said first voltage respectively and further turned off for at least a partial period in a period when said input signal in said inverter circuit reaches said voltage corresponding to said logical threshold voltage of said inverter circuit from said second voltage for changing from said second voltage to said first voltage thereby not functioning substantially as a capacitor.

3. The delay circuit according to claim 1, wherein
said first transistor has a threshold voltage in the vicinity of the voltage difference between the output side and the input side of said inverter circuit at the time when said input signal in said inverter circuit reaches said voltage corresponding to said logical threshold voltage of said inverter circuit from said first voltage.

4. The delay circuit according to claim 1, wherein
a plurality of said inverter circuits are serially connected with each other, and
said first transistor is connected in parallel to at least one said inverter circuit among said plurality of inverter circuits.

5. The delay circuit according to claim 1, wherein
said first voltage and said second voltage are a low voltage and a high voltage respectively,
said inverter circuit includes a p-type second transistor connected to a supply source of said high voltage and an n-type third transistor, connected to a supply source of said low voltage, having a gate width of a magnitude not more than the gate width of said second transistor and a gate length larger than the gate length of said second transistor or a gate width smaller than the gate width of said second transistor and a gate length of a magnitude not less than the gate length of said second transistor, and
said first transistor is a p-type transistor.

6. The delay circuit according to claim 5, wherein
said first transistor, said second transistor and said third transistor include polycrystalline thin-film transistors formed on a single insulated substrate respectively.

7. The delay circuit according to claim 5, wherein
a plurality of said inverter circuits are serially connected with each other,
said first transistor is connected in parallel to at least one said inverter circuit among said plurality of inverter circuits, and
said inverter circuit not connected in parallel with said first transistor includes a p-type fourth transistor connected to a supply source of said high voltage and an n-type fifth transistor, connected to a supply source of said low voltage, having a gate width substantially identical to the gate width of said fourth transistor.

8. The delay circuit according to claim 1, wherein
said first voltage and said second voltage are a high voltage and a low voltage respectively,
said inverter circuit includes a p-type second transistor connected to a supply source of said high voltage and an n-type third transistor, connected to a supply source of said low voltage, having a gate width of a magnitude not less than the gate width of said second transistor and a gate length smaller than the gate length of said second transistor or a gate width larger than the gate width of said second transistor and a gate length of a magnitude not more than the gate length of said second transistor, and
said first transistor is an n-type transistor.

9. The delay circuit according to claim 8, wherein
said first transistor, said second transistor and said third transistor include polycrystalline thin-film transistors formed on a single insulated substrate respectively.

10. The delay circuit according to claim 8, wherein
a plurality of said inverter circuits are serially connected with each other,
said first transistor is connected in parallel to at least one said inverter circuit among said plurality of inverter circuits, and
said inverter circuit not connected in parallel with said first transistor includes a p-type fourth transistor connected to a supply source of said high voltage and an n-type fifth transistor, connected to a supply source of said low voltage, having a gate width substantially identical to the gate width of said fourth transistor.

11. A display including a delay circuit, comprising:
a shift register circuit outputting a signal shifted in timing;
a buffer including a delay circuit connected to the output side of said shift register circuit; and
a switching transistor having a gate connected to the output side of said buffer as well as a source and a drain, one of which is connected to a signal line for supplying a video signal so that the other one is connected to a drain line connected to an image display portion, wherein
said delay circuit includes an inverter circuit having a prescribed logical threshold voltage and a first transistor connected in parallel to said inverter circuit, and
said first transistor is turned on when an input signal in and an output signal from said inverter circuit are at a first voltage and a second voltage respectively and further turned on for at least a partial period in a period when said input signal in said inverter circuit reaches a voltage corresponding to said logical threshold voltage of said inverter circuit from said first voltage for changing from said first voltage to said second voltage thereby functioning substantially as a capacitor.

12. The display including a delay circuit according to claim 11, wherein
said buffer includes a first delay circuit including a first inverter circuit having a first logical threshold voltage and said first transistor of a first conductive type and a second delay circuit including a second inverter circuit having a second logical threshold voltage and said first transistor of a second conductive type, and
said switching transistor includes a first switching transistor of said first conductive type having a gate connected to the output side of said first delay circuit, a source connected to said signal line and a drain connected to said drain line and a second switching transistor of said second conductive type having a gate connected to the output side of said second delay circuit, a drain connected to said signal line and a source connected to said drain line.

13. The display including a delay circuit according to claim 11, wherein
said first transistor is turned off when said input signal in and said output signal from said inverter circuit are at said second voltage and said first voltage respectively and further turned off for at least a partial period in a period when said input signal in said inverter circuit reaches said voltage corresponding to said logical threshold voltage of said inverter circuit from said second voltage for changing from said second voltage to said first voltage thereby not functioning substantially as a capacitor.

14. The display including a delay circuit according to claim 13, provided with a plurality of stages of said shift register circuits, said buffers including said delay circuits and said switching transistors, wherein
an input signal in said inverter circuit of said delay circuit of next said stage but one to prescribed said stage simultaneously changes from said first voltage to said second voltage when an input signal in said inverter circuit of said delay circuit of said prescribed stage changes from said second voltage to said first voltage, and
said first transistor connected in parallel to said inverter circuit of said prescribed stage does not function substantially as a capacitor for at least a partial period in a period when an input signal in said inverter circuit of said prescribed stage reaches a voltage corresponding to the logical threshold voltage of said inverter circuit of said prescribed stage from said second voltage while said first transistor connected in parallel to said inverter circuit of said next stage but one to said prescribed stage functions substantially as a capacitor for at least a partial period in a period when an input signal in said inverter circuit of said next stage but one to said prescribed stage reaches a voltage corresponding to the logical threshold voltage of said inverter circuit of said next stage but one to said prescribed stage from said first voltage so that the time delay of an output signal output from said buffer including said delay circuit of said prescribed stage to corresponding said switching transistor is smaller than the time delay of an output signal output from said buffer including said delay circuit of said next stage but one to said prescribed stage to corresponding said switching transistor, whereby change timing for the voltage of said output signal from said buffer including said delay circuit of said prescribed stage does not overlap with change timing for the voltage of said output signal from said buffer including said delay circuit of said next stage but one to said prescribed stage.

15. The display including a delay circuit according to claim 11, wherein
said first transistor has a threshold voltage in the vicinity of the voltage difference between the output side and the input side of said inverter circuit at the time when said input signal in said inverter circuit reaches said voltage corresponding to said logical threshold voltage of said inverter circuit from said first voltage.

16. The display including a delay circuit according to claim 11, wherein
a plurality of said inverter circuits are serially connected with each other, and
said first transistor is connected in parallel to at least one said inverter circuit among said plurality of inverter circuits.

17. The display including a delay circuit according to claim 11, wherein
said first voltage and said second voltage are a low voltage and a high voltage respectively,
said inverter circuit includes a p-type second transistor connected to a supply source of said high voltage and an n-type third transistor, connected to a supply source of said low voltage, having a gate width of a magnitude not more than the gate width of said second transistor and a gate length larger than the gate length of said second transistor or a gate width smaller than the gate width of said second transistor and a gate length of a magnitude not less than the gate length of said second transistor, and
said first transistor is a p-type transistor.

18. The display including a delay circuit according to claim 17, wherein
said first transistor, said second transistor and said third transistor include polycrystalline thin-film transistors formed on a single insulated substrate respectively.

19. The display including a delay circuit according to claim 17, wherein
a plurality of said inverter circuits are serially connected with each other,
said first transistor is connected in parallel to at least one said inverter circuit among said plurality of inverter circuits, and
said inverter circuit not connected in parallel with said first transistor includes a p-type fourth transistor connected to a supply source of said high voltage and an n-type fifth transistor, connected to a supply source of said low voltage, having a gate width substantially identical to the gate width of said fourth transistor.

20. The display including a delay circuit according to claim 11, wherein
said first voltage and said second voltage are a high voltage and a low voltage respectively,
said inverter circuit includes a p-type second transistor connected to a supply source of said high voltage and an n-type third transistor, connected to a supply source of said low voltage, having a gate width of a magnitude not less than the gate width of said second transistor and a gate length smaller than the gate length of said second transistor or a gate width larger than the gate width of said second transistor and a gate length of a magnitude not more than the gate length of said second transistor, and
said first transistor is an n-type transistor.

21. The display including a delay circuit according to claim 20, wherein
said first transistor, said second transistor and said third transistor include polycrystalline thin-film transistors formed on a single insulated substrate respectively.

22. The display including a delay circuit according to claim 20, wherein
a plurality of said inverter circuits are serially connected with each other,
said first transistor is connected in parallel to at least one said inverter circuit among said plurality of inverter circuits, and
said inverter circuit not connected in parallel with said first transistor includes a p-type fourth transistor connected to a supply source of said high voltage and an n-type fifth transistor, connected to a supply source of said low voltage, having a gate width substantially identical to the gate width of said fourth transistor.

23. The display including a delay circuit according to claim 11, wherein
said image display portion includes liquid crystals.
